(19) United States
(12) Patent Application Publication
(10) Pub. No.: US 2026/0143816 A1
(43) Pub. Date: May 21, 2026

(54) DISPLAY DEVICE

(71) Applicant: Japan Display Inc., Tokyo (JP)

(72) Inventor: Hitoshi TANAKA, Tokyo (JP)

(21) Appl. No.: 19/386,473

(22) Filed: Nov. 12, 2025

(30) Foreign Application Priority Data
Nov. 20, 2024 (JP) 2024-202116

(51) Int. Cl. H10D 86/40; H10D 86/60; G02F 1/1362

(52) U.S. Cl. CPC H10D 86/441; H10D 86/60; G02F 1/136286

(57) ABSTRACT

According to an aspect, a display device includes: a substrate having a display region and a peripheral region different from the display region; a plurality of pixel electrodes provided in the display region of the substrate; a plurality of scanning lines extending in a first direction; a plurality of signal lines extending in a second direction intersecting the first direction; and a drive circuit coupled to a first end of the signal lines. The signal lines each have a first portion overlapping the display region and a second portion coupled to the first portion and overlapping the peripheral region on a second end side of the signal lines. A width in the first direction of the second portion is larger than a width in the first direction of the first portion.

### CROSS-REFERENCE TO RELATED APPLICATION

This application claims the benefit of priority from Japanese Patent Application No. 2024-202116 filed on November 20, 2024, the entire contents of which are incorporated herein by reference.

### BACKGROUND

### 1. Technical Field

What is disclosed herein relates to a display device.

### 2. Description of the Related Art

Japanese Patent Application Laid-open Publication No. 2008-203621 and U.S. Unexamined Patent Application Publication No. 2006/0290859 disclose techniques related to a display device including a plurality of signal lines and a plurality of scanning lines. Various such display devices are known, including head-mounted displays (hereinafter also referred to as "HMDs") used in virtual reality (VR) systems.

Display devices, such as HMDs, are expected to achieve high definition, and the width of the signal lines needs to be reduced. If the width of the signal lines is reduced, the adhesion between the signal lines and the insulating film provided with the signal lines decreases, and the signal lines may possibly delaminate.

For the foregoing reasons, there is a need for a display device capable of reducing delamination of signal lines.

### SUMMARY

According to an aspect, a display device includes: a substrate having a display region and a peripheral region different from the display region; a plurality of pixel electrodes provided in the display region of the substrate; a plurality of scanning lines extending in a first direction; a plurality of signal lines extending in a second direction intersecting the first direction; and a drive circuit coupled to a first end of the signal lines. The signal lines each have a first portion overlapping the display region and a second portion coupled to the first portion and overlapping the peripheral region on a second end side of the signal lines. A width in the first direction of the second portion is larger than a width in the first direction of the first portion.

### BRIEF DESCRIPTION OF THE DRAWINGS

FIG. 1 is a configuration diagram of an example of a display system according to an embodiment;

FIG. 2 is a schematic diagram of an example of the relative relation between a display device and the eyes of a user;

FIG. 3 is a block diagram of an example of the configuration of the display system according to the embodiment;

FIG. 4 is a circuit diagram of a pixel array in a display region according to the embodiment;

FIG. 5 is a schematic diagram of an example of a display panel according to the embodiment;

FIG. 6 is a sectional view schematically illustrating a section of the display panel according to the embodiment;

FIG. 7 is an enlarged plan view of a region A in FIG. 5;

FIG. 8 is an enlarged plan view of a first portion and a second portion of signal lines;

FIG. 9 is a sectional view along line IX-IX' of FIG. 7; and

FIG. 10 is a schematic diagram of an arrangement pattern of the signal lines of the display device according to a comparative example.

### DETAILED DESCRIPTION

Exemplary aspects (embodiments) to embody the present disclosure are described below in greater detail with reference to the accompanying drawings. The content described in the embodiments below is not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present disclosure and the figures, components similar to those previously described with reference to previous figures are denoted by the same reference numerals, and detailed explanation thereof may be appropriately omitted.

When the term "on" is used to describe an aspect where a first structure is disposed on a second structure in the present disclosure, it includes both of the following cases unless otherwise noted: a case where the first structure is disposed directly on and in contact with the second structure, and a case where the first structure is disposed on the second structure with another structure interposed therebetween.

### Embodiments

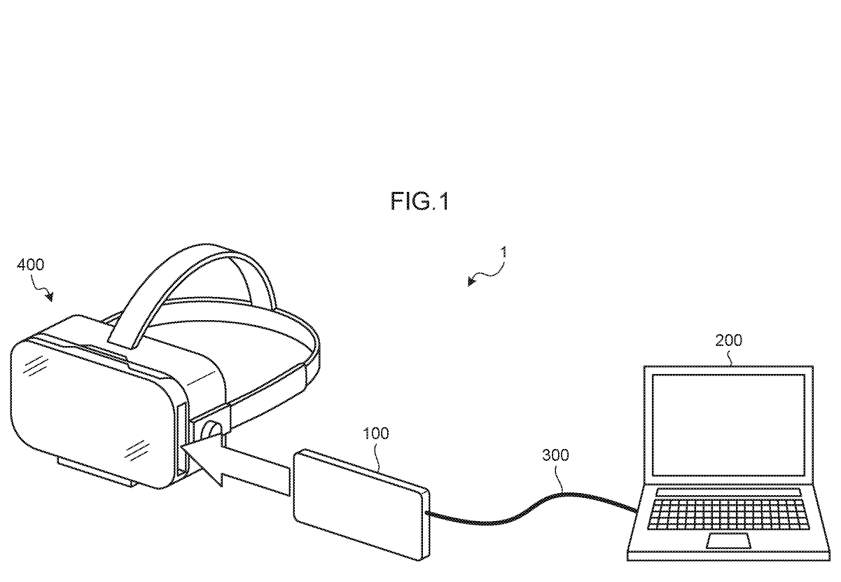

FIG. 1 is a configuration diagram of an example of a display system according to an embodiment. A display system 1 according to the present embodiment is a display system that changes images in synchronization with movement of the user. The display system 1 is, for example, a virtual reality (VR) system that three-dimensionally displays VR images of three-dimensional objects or the like in a virtual space and changes the three-dimensional images depending on changes of the orientation (position) of the user's head, thereby providing the user with a sense of virtual reality.

As illustrated in FIG. 1, the display system 1 includes a display device 100 and a control device 200, for example. The display device 100 and the control device 200 can receive and transmit information (signals) via a cable 300. Examples of the cable 300 include, but are not limited to, a universal serial bus (USB) cable, a high-definition multimedia interface (HDMI) (registered trademark) cable, etc. The display device 100 and the control device 200 may be capable of receiving and transmitting information through wireless communications.

The display device 100 includes display panels. While the display panel is a liquid crystal display, for example, it may be an organic electro-luminescence panel, a μ-OLED panel, a μ-LED panel, a mini-LED panel, or other panels.

The display device 100 is fixed to a wearable member 400. Examples of the wearable member 400 include, but are not limited to, a headset, goggles, a helmet and a mask that cover both eyes of the user, etc. The wearable member 400 is worn on the user's head. When the wearable member 400 is worn, it is positioned in front of the user so as to cover both eyes of the user. The wearable member 400 functions as an immersive wearable member when the display device 100 fixed inside the wearable member 400 is positioned in front of both eyes of the user. The wearable member 400 may include an output part that outputs sound signals or the like output from the control device 200. The wearable member 400 may include the functions of the control device 200.

While the display device 100 in the example illustrated in FIG. 1 is configured to be slotted into the wearable member 400, it may be fixed to the wearable member 400. In other words, the display system 1 may be composed of a wearable display device including the wearable member 400 and the display device 100, and the control device 200.

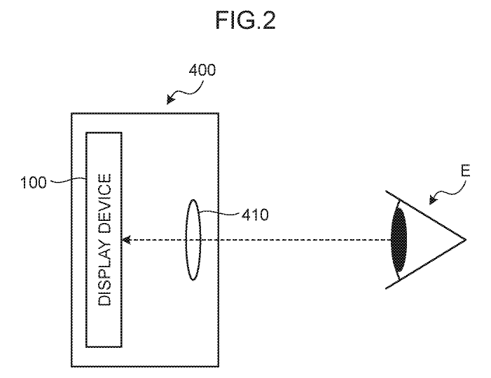

FIG. 2 is a schematic diagram of an example of the relative relation between the display device and the eyes of the user. As illustrated in FIG. 2, the wearable member 400 includes a lens 410 corresponding to both eyes of the user, for example. The lens 410 is a magnifying lens to form an image in the eyes of the user. When the wearable member 400 is worn on the user's head, the lens 410 is positioned in front of the user's eyes E. The user visually recognizes a display region of the display device 100 magnified by the lens 410. Therefore, the display device 100 needs to increase the resolution to clearly display an image (screen). While the configuration according to the present disclosure includes one lens 410, for example, it may include a plurality of lenses 410, and the display device 100 may be positioned at a position other than in front of the eyes.

The control device 200, for example, displays images on the display device 100. The control device 200 may be an electronic apparatus, such as a personal computer and a gaming device. Examples of the virtual images include, but are not limited to, computer graphic video images, 360-degree real video images, etc. The control device 200 outputs, to the display device 100, a three-dimensional image generated using the parallax of both eyes of the user. The control device 200 outputs, to the display device 100, images for the right eye and the left eye that follow the changes of the orientation of the user's head.

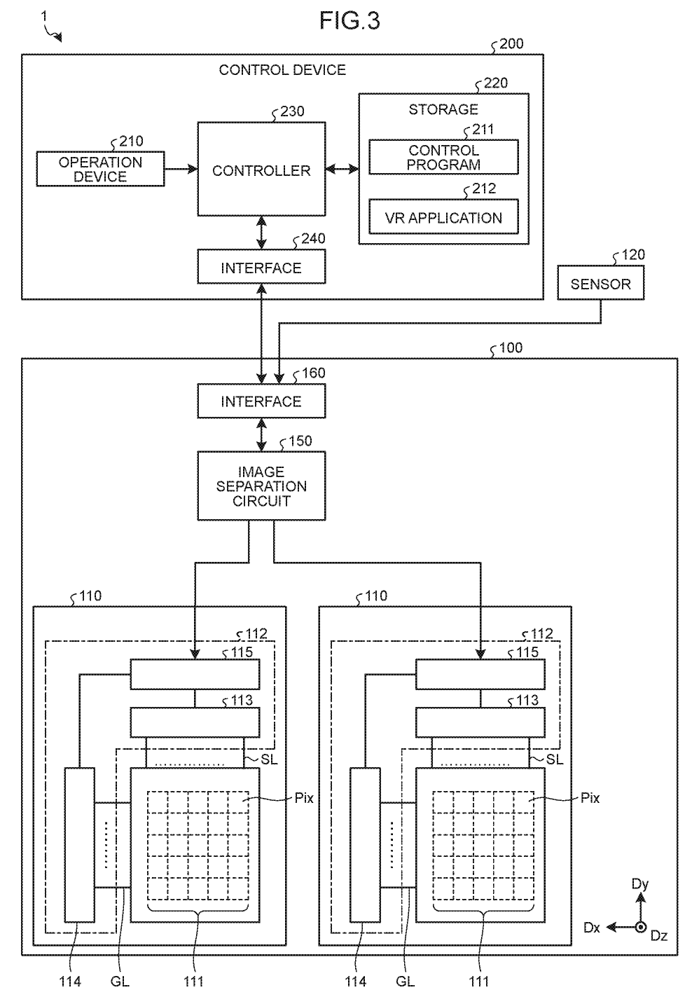

FIG. 3 is a block diagram of an example of the configuration of the display system according to the embodiment. As illustrated in FIG. 3, the display device 100 includes two display panels 110, a sensor 120, an image separation circuit 150, and an interface 160.

The display device 100 is composed of two display panels 110: one is used as the display panel 110 for the left eye, and the other is used as the display panel 110 for the right eye.

The two display panels 110 each have a display region 111 and a display control circuit 112. The display panel 110 is provided with a light source device (backlight unit IL, which will be described later), not illustrated, that irradiates the display region 111 with light from behind.

In the display region 111, P₀×Q₀pixels Pix (P₀ pixels Pix in the row direction and Q₀ pixels Pix in the column direction) are arrayed in a two-dimensional matrix (row-column configuration). In the present embodiment, P₀ is 2880, and Q₀ is 1700. The row direction corresponds to a first direction Dx, and the column direction corresponds to a second direction Dy. FIG. 3 schematically illustrates the array of the pixels Pix, and the array of the pixels Pix will be described later in greater detail.

The display panel 110 includes scanning lines GL extending in the first direction Dx and signal lines SL extending in the second direction Dy that intersects the first direction Dx. The display panel 110 includes 2880 signal lines SL and 1700 scanning lines GL, for example. In the display panel 110, the region surrounded by the signal lines SL and the scanning lines GL is provided with the pixel Pix. The pixel Pix includes a switching element (thin-film transistor (TFT)) coupled to the signal line SL and the scanning line GL, and a pixel electrode coupled to the switching element. One scanning line GL is coupled to a plurality of pixels Pix disposed along the extending direction of the scanning line GL. One signal line SL is coupled to a plurality of pixels Pix disposed along the extending direction of the signal line SL.

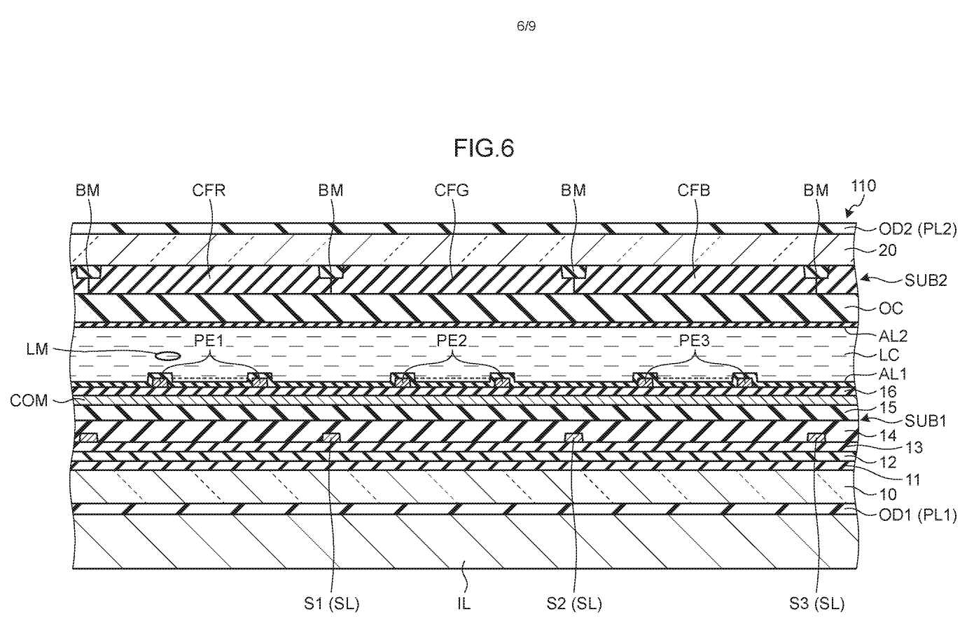

In the following description, the first direction Dx is one direction in a plane parallel to the surface of a first substrate 10 (refer to FIG. 6). The second direction Dy is one direction in the plane parallel to the surface of the first substrate 10 and is orthogonal to the first direction Dx. The second direction Dy may intersect the first direction Dx without being orthogonal thereto. A third direction Dz is a direction orthogonal to the first direction Dx and the second direction Dy. The third direction Dz is the direction normal to the surface of the first substrate 10. The term "plan view" refers to the positional relation when viewed along a direction perpendicular to the surface of the first substrate 10.

The display region 111 of one display panel 110 of the two display panels 110 is for the right eye, and the display region 111 of the other display panel 110 is for the left eye. The present embodiment describes a case where the display panel 110 includes the two display panels 110 for the left eye and the right eye. The display device 100, however, does not necessarily include two display panels 110 as described above. The display panel 110, for example, may include one display panel 110. In this case, the display region 111 of the display panel 110 may be divided into two parts such that the right half region displays images for the right eye and the left half region displays images for the left eye.

The display control circuit 112 includes a driver integrated circuit (IC) 115, a signal line coupling circuit 113, and a scanning line drive circuit 114. The signal line coupling circuit 113 is electrically coupled to the signal lines SL. The driver IC 115 causes the scanning line drive circuit 114 to control ON/OFF of the switching elements (e.g., TFT) for controlling the operation (light transmittance) of the pixels Pix. The scanning line drive circuit 114 is electrically coupled to the scanning lines GL.

The sensor 120 detects information that enables determination of the orientation of the user's head. The sensor 120, for example, detects information indicating the movement of the display device 100 and/or the wearable member 400, and the display system 1 determines the orientation of the head of the user wearing the display device 100 on the head based on the information indicating the movement of the display device 100 and/or the wearable member 400.

The sensor 120 detects the information that enables determination of the direction of the line of sight using at least one of the angle, acceleration, angular velocity, azimuth, and distance of the display device 100 and/or the wearable member 400, for example. Examples of the sensor 120 include, but are not limited to, a gyro sensor, an acceleration sensor, an azimuth sensor, etc. The sensor 120 may detect the angle and angular velocity of the display device 100 and/or the wearable member 400 by a gyro sensor, for example. The sensor 120 may detect the direction and magnitude of acceleration acting on the display device 100 and/or the wearable member 400 by an acceleration sensor, for example.

The sensor 120 may detect the azimuth of the display device 100 by an azimuth sensor, for example. The sensor 120 may detect the movement of the display device 100 and/or the wearable member 400 by a distance sensor or a global positioning system (GPS) receiver, for example. The sensor 120 may be any other sensor, such as an optical sensor, or a combination of a plurality of sensors, as long as it is a sensor that detects the orientation of the user's head, changes in the line of sight, movement, or the like. The sensor 120 is electrically coupled to the image separation circuit 150 via the interface 160, which will be described later.

The image separation circuit 150 receives image data for the left eye and image data for the right eye transmitted from the control device 200 via the cable 300. The image separation circuit 150 transmits the image data for the left eye to the display panel 110 that displays images for the left eye and transmits the image data for the right eye to the display panel 110 that displays images for the right eye.

The interface 160 includes a connector to which the cable 300 (FIG. 1) is coupled. The interface 160 receives signals from the control device 200 via the coupled cable 300. The image separation circuit 150 outputs the signals received from the sensor 120 to the control device 200 via the interface 160 and an interface 240. The signals received from the sensor 120 include the information that enables determination of the direction of the line of sight described above. Alternatively, the signals received from the sensor 120 may be output directly to a controller 230 of the control device 200 via the interface 160. The interface 160 may be a wireless communication device, for example, and transmit and receive information to and from the control device 200 through wireless communications.

The control device 200 includes an operation device 210, a storage 220, the controller 230, and the interface 240.

The operation device 210 receives operations of the user. The operation device 210 is an input device, such as a keyboard, buttons, and a touch screen. The operation device 210 is electrically coupled to the controller 230. The operation device 210 outputs information corresponding to the operations to the controller 230.

The storage 220 stores therein computer programs and data. The storage 220 temporarily stores therein the results of processing by the controller 230. The storage 220 includes a storage medium. Examples of the storage medium include, but are not limited to, ROM, RAM, a memory card, an optical disc, a magneto-optical disc, etc. The storage 220 may store therein data of images to be displayed on the display device 100.

The storage 220 stores therein a control program 211 and a VR application 212, for example. The control program 211 can implement functions related to various controls for operating the control device 200, for example. The VR application 212 can implement functions to display virtual reality images on the display device 100. The storage 220, for example, can store therein various kinds of information, such as data indicating the detection results of the sensor 120, received from the display device 100.

Examples of the controller 230 include, but are not limited to, a micro control unit (MCU), a central processing unit (CPU), etc. The controller 230 can collectively control the operations of the control device 200. The various functions of the control device 200 are implemented based on the control by the controller 230.

The controller 230 includes a graphics processing unit (GPU) that generates images to be displayed, for example. The GPU generates images to be displayed on the display device 100. The controller 230 outputs the images generated by the GPU to the display device 100 via the interface 240. While the controller 230 of the control device 200 according to the present embodiment includes a GPU, the present embodiment is not limited thereto. For example, the GPU may be provided in the display device 100 or the image separation circuit 150 of the display device 100. In this case, the display device 100 acquires data from the control device 200 or an external electronic apparatus, for example, and the GPU generates the images based on the data.

The interface 240 includes a connector to which the cable 300 (refer to FIG. 1) is coupled. The interface 240 receives signals from the display device 100 via the cable 300. The interface 240 outputs signals received from the controller 230 to the display device 100 via the cable 300. The interface 240 may be a wireless communication device, for example, and may transmit and receive information to and from the display device 100 through wireless communications.

When the controller 230 executes the VR application 212, it displays images corresponding to the movement of the user (display device 100) on the display device 100. When the controller 230 detects a change in the user (display device 100) while an image is being displayed on the display device 100, the controller 230 changes the image being displayed on the display device 100 to an image in the direction of the change. When starting to generate an image, the controller 230 generates an image based on a reference point of view and a reference line of sight in the virtual space. When the controller 230 detects a change in the user (display device 100), the controller 230 changes the point of view or the line of sight for generating the image to be displayed, from the reference point view or the reference line of sight to the point view or the line of sight corresponding to the movement of the user (display device 100). The controller 230 displays, on the display device 100, an image based on the changed point of view or line of sight.

For example, the controller 230 detects the movement of the user's head to the right direction based on the detection results of the sensor 120. In this case, the controller 230 changes the currently displayed image to an image obtained when the line of sight is moved to the right direction. The user can visually recognize the image on the right side of the image being displayed on the display device 100.

When the controller 230 detects the movement of the display device 100 based on the detection results of the sensor 120, for example, the controller 230 changes the image according to the detected movement. If the controller 230 detects that the display device 100 has moved forward, the controller 230 changes the currently displayed image to an image to be displayed when the display device 100 moves forward. If the controller 230 detects that the display device 100 has moved backward, the controller 230 changes the currently displayed image to an image to be displayed when the display device 100 moves backward. The user can visually recognize the image corresponding to the direction of his/her movement from the image being displayed on the display device 100.

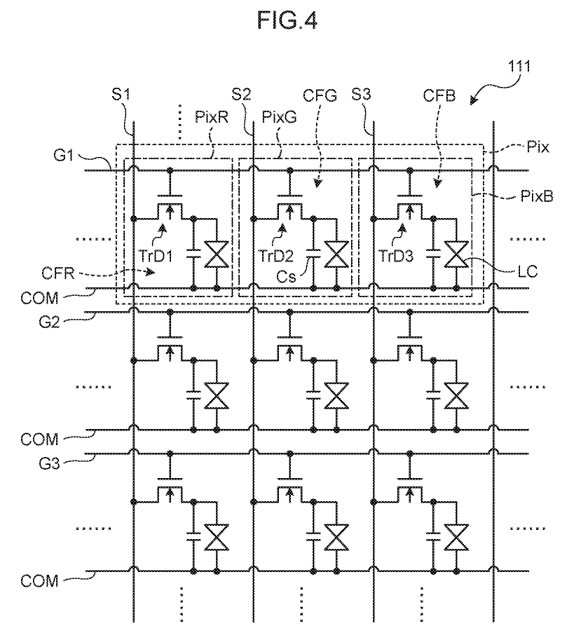

FIG. 4 is a circuit diagram of the pixel array in the display region according to the embodiment. In the following description, the scanning lines GL described above collectively refer to scanning lines G1, G2, and G3. The signal lines SL described above collectively refer to signal lines S1, S2, and S3. While the scanning lines GL and the signal lines SL are orthogonal to each other in the example illustrated in FIG. 4, the present embodiment is not limited thereto. For example, the scanning lines GL and the signal lines SL are not necessarily orthogonal to each other.

As illustrated in FIG. 4, the display region 111 is provided with switching elements TrD1, TrD2, and TrD3 of pixels PixR, PixG, and PixB, the signal lines SL, the scanning lines GL, and other components. The signal lines S1, S2, and S3 are wiring for supplying pixel signals to pixel electrodes PE1, PE2, and PE3 (refer to FIG. 6). The scanning lines G1, G2, and G3 are wiring for supplying gate signals that drive the switching elements TrD1, TrD2, and TrD3.

The pixel Pix in the display region 111 includes a plurality of arrayed pixels PixR, PixG, and PixB. In the following description, the pixels PixR, PixG, and PixB may be collectively referred to as the pixels Pix. The pixels PixR, PixG, and PixB include the switching elements TrD1, TrD2, and TrD3, respectively, and a capacitor of a liquid crystal layer LC. The switching elements TrD1, TrD2, and TrD3 are composed of a thin-film transistor and are composed of an n-channel metal oxide semiconductor (MOS) TFT in this example. A sixth insulating film 16 (refer to FIG. 6) is provided between the pixel electrodes PE1, PE2, and PE3 and a common electrode COM, which will be described later, and a holding capacitor Cs illustrated in FIG. 4 is formed by them.

In color filters CFR, CFG, and CFB illustrated in FIG. 4, color regions colored in three colors of red (first color: R), green (second color: G), and blue (third color: B), for example, are periodically arrayed. The three color regions R, G, and B correspond as one set to the pixels PixR, PixG, and PixB, respectively, illustrated in FIG. 4 described above. The pixels PixR, PixG, and PixB corresponding to the three color regions serve as one set. The color filter may include four or more color regions. The pixels PixR, PixG, and PixB may be referred to as sub-pixels.

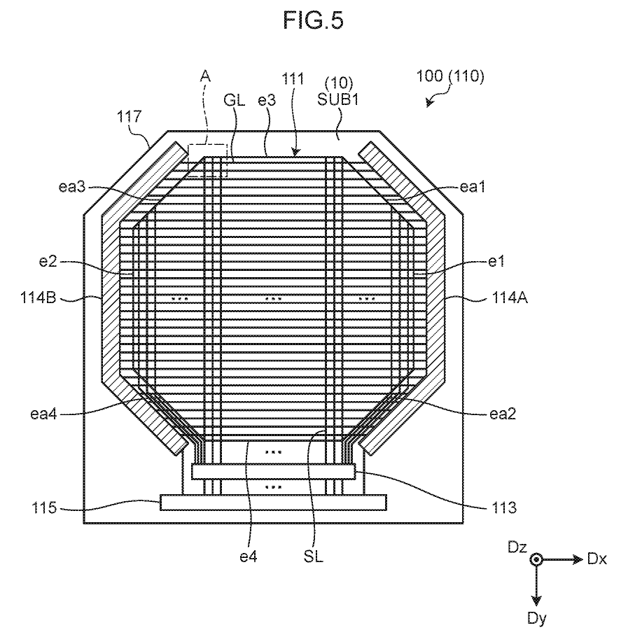

FIG. 5 is a schematic diagram of an example of the display panel according to the embodiment. FIG. 5 does not illustrate some of the signal lines to make the drawing easier to see.

As illustrated in FIG. 5, the display region 111 of the display panel 110 has a polygonal shape in plan view. More specifically, the display region 111 is octagonal in shape and has a first side e1, a second side e2, a third side e3, a fourth side e4, a first inclined side ea1, a second inclined side ea2, a third inclined side ea3, and a fourth inclined side ea4. The region between the outer edge of the first substrate 10 of the display panel 110 and each side of the display region 111 is a peripheral region 117.

The first side e1 is a side positioned on the right side of the outer periphery of the display region 111 and extends in the second direction Dy. The second side e2 is positioned on the side opposite to the first side e1, that is, the left side of the outer periphery of the display region 111 and extends in the second direction Dy. The third side e3 is a side positioned on the upper side of the outer periphery of the display region 111 and extends in the first direction Dx. The fourth side e4 is a side positioned on the side opposite to the third side e3, that is, the lower side of the outer periphery of the display region 111 and extends in the first direction Dx.

The lengths in the second direction Dy of the signal lines SL provided in the region corresponding to the third side e3 and the fourth side e4 are equal. The lengths in the first direction Dx of the scanning lines GL provided in the region corresponding to the first side e1 and the second side e2 are equal.

The first inclined side ea1 is the side between the first side e1 and the third side e3, and is coupled to one end (upper end in FIG. 5) of the first side e1 and inclined with respect to the second direction Dy. The second inclined side ea2 is the side between the first side e1 and the fourth side e4, and is coupled to the other end (lower end in FIG. 5) of the first side e1 and inclined with respect to the second direction Dy. The third inclined side ea3 is the side between the second e2 and the third side e3, and is coupled to one end of the second side e2 and inclined with respect to the second direction Dy. The fourth inclined side ea4 is the side between the second side e2 and the fourth side e4, and is coupled to the other end of the second side e2 and inclined with respect to the second direction Dy.

The first inclined side ea1 and the second inclined side ea2 according to the present embodiment are provided in line symmetry with respect to a virtual line passing through the midpoint of the first side e1 and parallel to the first direction Dx. The length in the second direction Dy of the signal line SL provided in the region corresponding to the first inclined side ea1 and the second inclined side ea2 is shorter as the distance from the right end of the third side e3 and the fourth side e4 increases (that is, the distance from the first side e1 decreases) in the first direction Dx.

The third inclined side ea3 and the fourth inclined side ea4 are provided in line symmetry with respect to a virtual line passing through the midpoint of the second side e2 and parallel to the first direction Dx. The length in the second direction Dy of the signal line SL provided in the region corresponding to the third inclined side ea3 and the fourth inclined side ea4 is shorter as the distance from the left end of the third side e3 and the fourth side e4 increases (that is, the distance from the second side e2 decreases) in the first direction Dx.

The first inclined side ea1 and the third inclined side ea3 are provided in line symmetry with respect to a virtual line passing through the midpoint of the third side e3 and parallel to the second direction Dy. The length in the first direction Dx of the scanning line GL provided in the region corresponding to the first inclined side ea1 and the third inclined side ea3 is shorter as the distance from one end of the first side e1 and the second side e2 increases (that is, the distance from the third side e3 decreases) in the second direction Dy.

The second inclined side ea2 and the fourth inclined side ea4 are provided in line symmetry with respect to a virtual line passing through the midpoint of the fourth side e4 and parallel to the second direction Dy. The length in the first direction Dx of the scanning line GL provided in the region corresponding to the second inclined side ea2 and the fourth inclined side ea4 is shorter as the distance from the other end of the first side e1 and the second side e2 increases (that is, the distance from the fourth side e4 decreases) in the second direction Dy.

A scanning line drive circuit 114A is disposed in the peripheral region 117 between the outer edge of the first substrate 10 of the display panel 110 and the first inclined side ea1, the first side e1, and the second inclined side ea2 of the display region 111. More specifically, the scanning line drive circuit 114A is provided extending along the first side e1, the first inclined side ea1, and the second inclined side ea2.

A scanning line drive circuit 114B is positioned on the side opposite to the scanning line drive circuit 114A, that is, in the peripheral region 117 between the outer edge of the first substrate 10 of the display panel 110 and the third inclined side ea3, the second side e2, and the fourth inclined side ea4 of the display region 111. More specifically, the scanning line drive circuit 114B is provided extending along the second side e2, the third inclined side ea3, and the fourth inclined side ea4. The right ends of the scanning lines GL are electrically coupled to the scanning line drive circuit 114A, and the left ends of the scanning lines GL are electrically coupled to the scanning line drive circuit 114B.

The signal line coupling circuit 113 is disposed in the peripheral region 117 between the outer edge of the first substrate 10 of the display panel 110 and the fourth side e4 of the display region 111. The signal line coupling circuit 113 is electrically coupled to first ends of the signal lines SL. The driver IC 115 is disposed in the peripheral region 117 between the outer edge of the first substrate 10 of the display panel 110 and the fourth side e4 of the display region 111. The driver IC 115 (drive circuit) is electrically coupled to the first ends of the signal lines SL via the signal line coupling circuit 113. The driver IC 115 is a circuit that controls the scanning line drive circuits 114A and 114B and the signal line coupling circuit 113.

In the example illustrated in FIG. 5, the signal lines SL are arrayed in the first direction Dx and each extend parallel to the second direction Dy. The scanning lines GL each extend parallel to a direction (first direction Dx) intersecting the signal lines SL. The direction in which the scanning lines GL extend is orthogonal to the direction in which the signal lines SL extend. Therefore, the pixels PixR, PixG, and PixB have a rectangular shape, for example. The pixels PixR, PixG, and PixB, however, do not necessarily have a rectangular shape. For example, the pixels PixR, PixG, and PixB may have a parallelogrammatic shape.

As described above, the display device 100 (display panel 110) according to the present embodiment has the display region 111 with a polygonal shape, for example. The present embodiment is not limited thereto, and the display region 111 of the display device 100 (display panel 110) may have other shapes, such as square and rectangular shapes. Alternatively, the corners of the display region 111 may have an arc-shaped curved part.

Next, the sectional structure of the display panel 110 is described with reference to FIG. 6. FIG. 6 is a sectional view schematically illustrating a section of the display panel according to the embodiment. In FIG. 6, an array substrate SUB1 is formed using the first substrate 10 having a light-transmitting property, such as a glass or resin substrate, as a base. The array substrate SUB1 includes a first insulating film 11, a second insulating film 12, a third insulating film 13, a fourth insulating film 14, a fifth insulating film 15, a sixth insulating film 16, the signal lines S1 to S3, the pixel electrodes PE1 to PE3, the common electrode COM, a first orientation film AL1, and other components on the surface of the first substrate 10 facing a counter substrate SUB2. In the following description, the direction from the array substrate SUB1 toward the counter substrate SUB2 is referred to as an upper side or simply as up.

The first insulating film 11 is positioned on the first substrate 10. The second insulating film 12 is positioned on the first insulating film 11. The third insulating film 13 is positioned on the second insulating film 12. The signal lines S1 to S3 are positioned on the third insulating film 13. The fourth insulating film 14 is positioned on the third insulating film 13 and covers the signal lines S1 to S3.

Wiring may be disposed on the fourth insulating film 14 if necessary. The wiring is covered by the fifth insulating film 15. In the present embodiment, the wiring is not provided. The first insulating film 11, the second insulating film 12, the third insulating film 13, and the sixth insulating film 16 are made of light-transmitting inorganic material, such as silicon oxide and silicon nitride. The fourth insulating film 14 and the fifth insulating film 15 are made of light-transmitting resin material and have a thicker thickness than the other insulating films made of inorganic material. The fifth insulating film 15, however, may be made of inorganic material.

The common electrode COM is positioned on the fifth insulating film 15. The common electrode COM is covered by the sixth insulating film 16. The sixth insulating film 16 is made of light-transmitting inorganic material, such as silicon oxide and silicon nitride.

The pixel electrodes PE1 to PE3 are positioned on the sixth insulating film 16 and face the common electrode COM with the sixth insulating film 16 interposed therebetween. The pixel electrodes PE1 to PE3 and the common electrode COM are made of light-transmitting conductive material, such as indium tin oxide (ITO) and indium zinc oxide (IZO). The pixel electrodes PE1 to PE3 are covered by the first orientation film AL1. The first orientation film AL1 also covers the sixth insulating film 16.

The counter substrate SUB2 is formed using a second substrate 20 having a light-transmitting property, such as a glass or resin substrate, as a base. The counter substrate SUB2 includes a light-shielding layer BM, the color filters CFR, CFG, and CFB, an overcoat layer OC, and a second orientation film AL2 on the surface of the second substrate 20 facing the array substrate SUB1.

As illustrated in FIG. 6, the light-shielding layer BM is positioned on the surface of the second substrate 20 facing the array substrate SUB1. The light-shielding layer BM defines the size of openings facing the respective pixel electrodes PE1 to PE3. The light-shielding layer BM is made of black resin material or light-shielding metal material.

The color filters CFR, CFG, and CFB are positioned on the surface of the second substrate 20 facing the array substrate SUB1 with their ends overlapping the light-shielding layer BM. The color filter CFR faces the pixel electrode PE1. The color filter CFG faces the pixel electrode PE2. The color filter CFB faces the pixel electrode PE3. For example, the color filters CFR, CFG, and CFB are made of resin material colored in red, green, and blue, respectively.

The overcoat layer OC covers the color filters CFR, CFG, and CFB. The overcoat layer OC is made of light-transmitting resin material. The second orientation film AL2 covers the overcoat layer OC. The first orientation film AL1 and the second orientation film AL2 are made of material having a horizontal orientation property, for example.

As described above, the counter substrate SUB2 includes the light-shielding layer BM, the color filters CFR, CFG, and CFB, and other components. The light-shielding layer BM is disposed in the region facing the wiring parts, such as the scanning lines G1, G2, and G3, the signal lines S1, S2, and S3, and the switching elements TrD1, TrD2, and TrD3 illustrated in FIG. 4.

While the counter substrate SUB2 includes the three color filters CFR, CFG, and CFB in FIG. 6, it may include four or more color filters. While the color filters CF are provided to the counter substrate SUB2, the display panel 110 may have what is called a color filter on array (COA) structure in which the color filters CF are provided to the array substrate SUB1.

The array substrate SUB1 and the counter substrate SUB2 are disposed with the first orientation film AL1 and the second orientation film AL2 facing each other. The liquid crystal layer LC is interposed between the first orientation film AL1 and the second orientation film AL2. The liquid crystal layer LC is made of negative liquid crystal material with negative dielectric anisotropy or positive liquid crystal material with positive dielectric anisotropy.

The array substrate SUB1 faces a backlight unit IL, and the counter substrate SUB2 is positioned on the display surface side. While various kinds of backlight units IL are applicable, detailed description of their structure is omitted.

A first optical element OD1 including a first polarizing plate PL1 is disposed on the outer surface of the first substrate 10 or the surface facing the backlight unit IL. A second optical element OD2 including a second polarizing plate PL2 is disposed on the outer surface of the second substrate 20 or the surface on the viewing position side. The first polarization axis of the first polarizing plate PL1 and the second polarization axis of the second polarizing plate PL2 are in a crossed-Nicoles positional relation in the X-Y plane, for example. The first optical element OD1 and the second optical element OD2 may include other optical functional elements, such as a retardation plate.

For example, when the liquid crystal layer LC is made of negative liquid crystal material and no voltage is applied to the liquid crystal layer LC, the liquid crystal molecules LM are initially oriented with their long axis along the X-direction in the X-Y plane. In contrast to this, when voltage is applied to the liquid crystal layer LC, that is, in an ON state where an electric field is generated between the common electrode COM and the pixel electrodes PE1 to PE3, the liquid crystal molecules LM are affected by the electric field, and their orientation state changes. In the ON state, the polarization state of incident linearly polarized light changes depending on the orientation state of the liquid crystal molecules LM as the linearly polarized light passes through the liquid crystal layer LC.

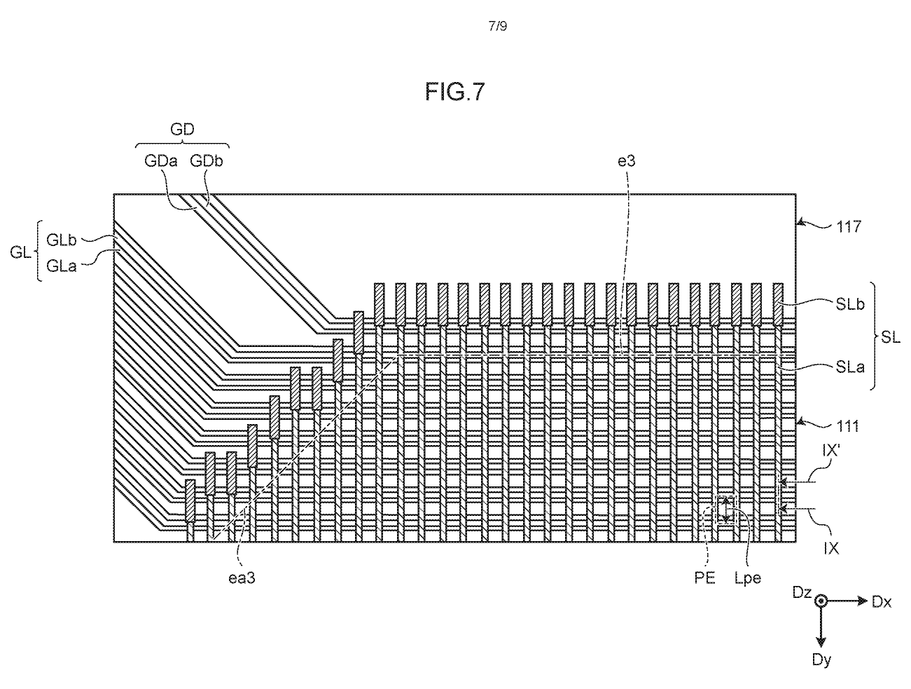

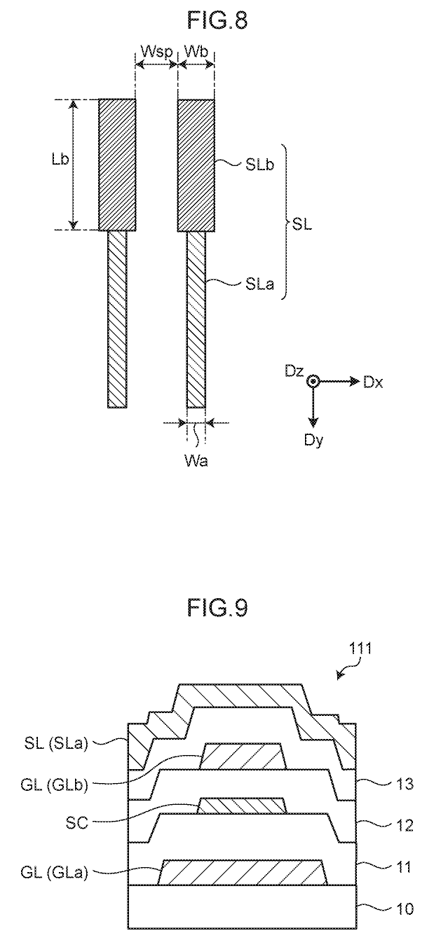

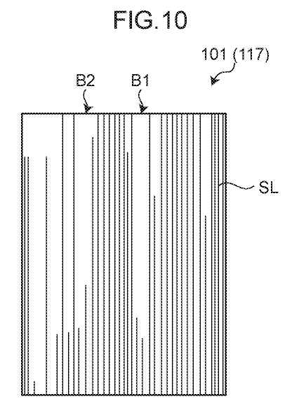

Next, the configuration of the signal line SL according to the present embodiment is described in greater detail with reference to FIGS. 7 to 9. FIG. 7 is an enlarged plan view of a region A in FIG. 5. FIG. 8 is an enlarged plan view of a first portion and a second portion of the signal lines. FIG. 9 is a sectional view along line IX-IX' of FIG. 7. FIG. 10 is a schematic diagram of an arrangement pattern of the signal lines of the display device according to a comparative example.

FIG. 7 illustrates the configuration of the signal lines SL and the scanning lines GL near the third side e3 and the third inclined side ea3 of the display region 111 in an enlarged manner. As illustrated in FIGS. 7 and 8, the signal lines SL each have a first portion SLa and a second portion SLb. The first portion SLa overlaps the display region 111. The second portion SLb is coupled to the first portion SLa and overlaps the peripheral region 117 located on the second end side of each signal line SL (that is, the side opposite to the driver IC 115 (refer to FIG. 5)).

The first portion SLa provided in the display region 111 extends in the second direction Dy and intersects a plurality of scanning lines GL in plan view. Among the second portions SLb provided in the peripheral region 117, at least a plurality of second portions SLb arrayed along the third side e3 do not overlap the scanning lines GL and are disposed on the peripheral region 117 side (outer edge side of the first substrate 10) than the scanning lines GL. Among the second portions SLb provided in the peripheral region 117, a plurality of second portions SLb arrayed along the third inclined side ea3 overlap the scanning lines GL arrayed between the display region 111 and the scanning line drive circuit 114B.

The peripheral region 117 according to the present embodiment is provided with guard wiring GD. The guard wiring GD includes a first guard line GDa and a second guard line GDb disposed overlapping each other. The guard wiring GD is provided to prevent static electricity and is supplied with a predetermined reference potential, such as ground potential. Alternatively, the guard wiring GD may be supplied with the same potential as that of the scanning lines GL as the reference potential. The second portions SLb of the signal lines SL are positioned on the peripheral region 117 side (outer edge side of the first substrate 10) than the guard wiring GD. While the ends of the second portions SLb of the signal lines SL overlap the guard wiring GD in FIG. 7, the present embodiment is not limited thereto. The ends may be disposed on the peripheral region 117 side than the guard wiring GD in such a manner as not to overlap the guard wiring GD.

As illustrated in FIG. 8, the width Wb in the first direction Dx of the second portion SLb of the signal lines SL is larger than the width Wa in the first direction Dx of the first portion SLa. Specifically, the width Wb in the first direction Dx of the second portion SLb is 2 μm or larger, and the width Wa in the first direction Dx of the first portion SLa is smaller than 2 μm. More preferably, the width Wb in the first direction Dx of the second portion SLb is larger than the width Wa in the first direction Dx of the first portion SLa by 0.3 μm or larger. In other words, when the width Wa in the first direction Dx of the first portion SLa is X μm, the width Wb in the first direction Dx of the second portion SLb is (X + 0.3) μm or larger.

The length Lb in the second direction Dy of the second portion SLb is longer than the length Lpe in the second direction Dy of one pixel electrode PE (refer to FIG. 7).

The width Wa in the first direction Dx of the first portion SLa is approximately 1.5 μm, for example. The width Wb in the first direction Dx of the second portion SLb is approximately 2.0 μm, for example. The length Lb in the second direction Dy of the second portion SLb is approximately 10.0 μm, for example. The width Wsp between adjacent second portions SLb is approximately 3.0 μm, for example.

In a display device 101 according to the comparative example illustrated in FIG. 10, the signal line SL does not have the second portion SLb and is formed to have a constant width from the first end to the second end. If the width of the signal line SL according to the comparative example is made thin to approximately 1 μm, for example, the adhesion between the signal line SL and the inorganic insulating film under the signal line SL may decrease. Alternatively, when patterning the signal line SL by photolithography and etching, variation with respect to the target line width in the manufacturing process may be relatively large, and the signal line SL may fail to be formed to have a constant width.

While the first end of the signal line SL is coupled to the circuits, such as the driver IC 115 and the signal line coupling circuit 113, or wiring, the second end of the signal line SL on the side opposite to the driver IC 115 is not coupled to anything. The second end of the signal line SL is more likely to delaminate than the first end (end on the driver IC 115 side). As a result, the signal line SL according to the comparative example tends to delaminate and disappear from the end positioned on the peripheral region 117 side as indicated by the arrows B1 and B2.

As illustrated in FIGS. 7 and 8, the signal lines SL according to the present embodiment each have the second portion SLb overlapping the peripheral region 117 and having a relatively large width, on the second end side (side opposite to the driver IC 115) where delamination is likely to occur. With this configuration, the adhesion of the signal lines SL in the peripheral region 117 is improved compared with the case where the signal lines do not have the second portion SLb and are formed to have a constant width. Therefore, this configuration can suppress delamination of the signal lines SL from the end.

As illustrated in FIGS. 7 and 9, the scanning line GL according to the present embodiment includes a first scanning line GLa and a second scanning line GLb. The first scanning line GLa and the second scanning line GLb are provided overlapping each other and extending in the same direction.

As illustrated in FIG. 9, the first scanning line GLa and the second scanning line GLb face each other in the direction perpendicular to the first substrate 10 with a semiconductor layer SC serving as the switching elements TrD1, TrD2 and TrD3 (refer to FIG. 4) interposed therebetween. The first scanning line GLa is positioned between the first substrate 10 and the semiconductor layer SC. The second scanning line GLb is positioned between the semiconductor layer SC and the signal line SL (first portion SLa) on the side opposite to the first scanning line GLa. The third insulating film 13 has steps reflecting the thicknesses of the semiconductor layer SC, the first scanning line GLa, and the second scanning line GLb.

The first portion SLa of the signal line SL positioned in the display region 111 is formed along the steps of the third insulating film 13. With this configuration, the contact area between the first portion SLa provided in the display region 111 and the third insulating film 13 increases compared with a case where the signal line SL is formed on a flat surface. The adhesion between the first portion SLa and the third insulating film 13 is also improved due to what is called an anchor effect. Therefore, the adhesion of the first portion SLa of the signal line SL provided in the display region 111 can be improved if the width Wa is reduced. While one scanning line GL is illustrated in FIG. 9, the signal line SL is disposed intersecting a plurality of scanning lines GL in the display region 111.

As described above, the display device 100 according to the present embodiment includes a substrate (first substrate 10), a plurality of pixel electrodes PE, a plurality of scanning lines GL, a plurality of signal lines SL, and a drive circuit (driver IC 115). The substrate has the display region 111 and the peripheral region 117 different from the display region 111. The pixel electrodes PE are provided in the display region 111 of the substrate. The scanning lines GL extend in the first direction Dx. The signal lines SL extend in the second direction Dy intersecting the first direction Dx. The drive circuit (driver IC 115) is coupled to the first end of the signal lines SL. The signal lines SL each have the first portion SLa and the second portion SLb. The first portion SLa overlaps the display region 111. The second portion SLb is coupled to the first portion SLa and overlaps the peripheral region 117 on the second end side of the signal lines SL. The width Wb in the first direction Dx of the second portion SLb is larger than the width Wa in the first direction Dx of the first portion SLa.

Thus, the display device 100 according to the present embodiment has the second portion SLb on the peripheral region 117 side, thereby improving the adhesion of the signal lines SL in the peripheral region 117. This configuration can suppress delamination of the signal lines SL from the end even if the width of the first portion SLa of the signal lines SL is reduced to achieve higher definition of display.

While the second portion SLb of the signal lines SL illustrated in FIGS. 7 and 8 has a rectangular shape extending in the second direction Dy, the present embodiment is not limited thereto. The second portion SLb may have other shapes, such as elliptical, oval, and polygonal shapes. In this case, the width Wb in the first direction Dx and the length Lb in the second direction Dy are the largest width Wb and the longest length Lb, respectively, of the second portion SLb.

The thicknesses of the semiconductor layer SC, the first scanning line GLa, the second scanning line GLb, and the insulating films in FIG. 9 are illustrated in an emphasized manner to facilitate the reader's understanding. The thicknesses of the semiconductor layer SC, the first scanning line GLa, the second scanning line GLb, and the insulating films according to the present embodiment are not limited to those in the example illustrated in FIG. 9.

While the exemplary embodiment of the present disclosure has been described, the embodiment is not intended to limit the present disclosure. The contents disclosed in the embodiment are given by way of example only, and various modifications may be made without departing from the spirit of the present disclosure. Appropriate modifications made without departing from the spirit of the present disclosure naturally fall within the technical scope of the present disclosure. At least one of various omissions, substitutions, and modifications of the components can be made without departing from the gist of the embodiments and modifications described above.

What is claimed is:

1. A display device comprising:
a substrate having a display region and a peripheral region different from the display region;
a plurality of pixel electrodes provided in the display region of the substrate;
a plurality of scanning lines extending in a first direction;
a plurality of signal lines extending in a second direction intersecting the first direction; and
a drive circuit coupled to a first end of the signal lines, wherein
the signal lines each have a first portion overlapping the display region and a second portion coupled to the first portion and overlapping the peripheral region on a second end side of the signal lines, and
a width in the first direction of the second portion is larger than a width in the first direction of the first portion.

2. The display device according to claim 1, wherein
the width in the first direction of the second portion is 2 μm or larger, and
the width in the first direction of the first portion is smaller than 2 μm.

3. The display device according to claim 1, wherein the width in the first direction of the second portion is (X + 0.3) μm or larger where the width in the first direction of the first portion is X μm.

4. The display device according to claim 1, wherein a length in the second direction of the second portion is longer than a length in the second direction of each of the pixel electrodes.
